(19) United States
(12) Patent Application Publication
(10) Pub. No.: US 2008/0038909 A1
(43) Pub. Date: Feb. 14, 2008

(54) Method of Fabricating Lateral Double Diffused Metal Oxide Semiconductor Field Effect Transistor

(76) Inventor: Woong Je Sung, Boocheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/782,667

(22) Filed: Jul. 25, 2007

(30) Foreign Application Priority Data
Aug. 9, 2006 (KR) 10-2006-0075420

(51) Int. Cl. H01L 21/425

(52) U.S. Cl. 438/531; 257/E21.473

(57) ABSTRACT

Provided is a method of fabricating a lateral double diffused MOSFET. In the method, ions are implanted onto a substrate to form a body region of the LDMOS transistor using a photoresist pattern as an ion implantation mask. Herein, the photoresist can be patterned to have a slope of with an angle in the range of 87° to 88°.

### CROSS-REFERENCE TO RELATED APPLICATION

The present application claims the benefit under 35 U.S.C. § 119 of Korean Patent Application No. 10-2006-0075420, filed Aug. 9, 2006, which is hereby incorporated by reference in its entirety.

### BACKGROUND

A metal oxide semiconductor field effect transistor (MOSFET) has high power gain because the MOSFET has a higher input impedance than a bipolar transistor, and its gate-driving circuits are very simply structured.

In addition, since the MOSFET is a unipolar device, it is advantageous in that there is no time delay caused by accumulation or recombination of minority carriers while the MOSFET is turned off.

Therefore, the MOSFET is increasingly being applied to a variety of fields such as a switching mode power supply, a lamp ballast, and a motor driving circuit.

Among various kinds of MOSFETs, a lateral double diffused MOSFET (LDMOS transistor) utilizing a planar diffusion technique is being widely used.

Meanwhile, it is important for the LDMOS transistor formed through a double diffusion process to obtain secure stable characteristics. However, there is a great change in threshold voltage depending on conditions of a photolithographic process for forming a p-type impurity doped well region.

### BRIEF SUMMARY

Embodiments of the present invention provide a method of fabricating a semiconductor device.

Embodiments also provide a method of fabricating a semiconductor device that can secure a stable threshold voltage.

In one embodiment, a method of fabricating a lateral double diffused metal oxide semiconductor field effect transistor (LDMOS transistor) includes implanting ions onto a substrate to form a body region of the LDMOS transistor using a photoresist as an ion implantation mask, wherein the photoresist has a slope having an angle in the range of 87° to 88°.

In another embodiment, a method of fabricating an LDMOS transistor includes implanting ions onto a substrate to form a body region of the LDMOS transistor using a photoresist as an ion implantation mask, wherein an exposure time of the photoresist is in the range of 400 msec to 480 msec, and a focus is in the range of −0.23 μm to −0.27 μm.

The details of one or more embodiments are set forth in the accompanying drawings and the description below. Other features will be apparent from the description and drawings, and from the claims.

### BRIEF DESCRIPTION OF THE DRAWINGS

FIG. 1 is an enlarged view illustrating a method of fabricating a lateral double diffused metal oxide semiconductor field effect transistor (LDMOS transistor) according to an embodiment.

FIG. 2 is a schematic view illustrating a photoresist slope.

FIG. 3 is a graph illustrating a relation between a photoresist slope and an effective channel length Leff.

FIG. 4 is a graph illustrating comparison results of threshold voltage characteristics respectively obtained under related art conditions and optimum conditions selected through experiments.

FIG. 5 is a graph illustrating a threshold voltage versus a bottom critical dimension according to a variation of a photoresist slope angle.

FIG. 6 is a graph illustrating a standard deviation of a threshold voltage versus a photoresist slope angle according to a variation of a bottom critical dimension.

FIG. 7 is a graph illustrating standard deviations of bottom and top critical dimensions versus a photoresist slope angle according to a variation of a bottom critical dimension.

### DETAILED DESCRIPTION

A method of fabricating a semiconductor device according to embodiments of the present invention will be described with reference to the accompanying drawings.

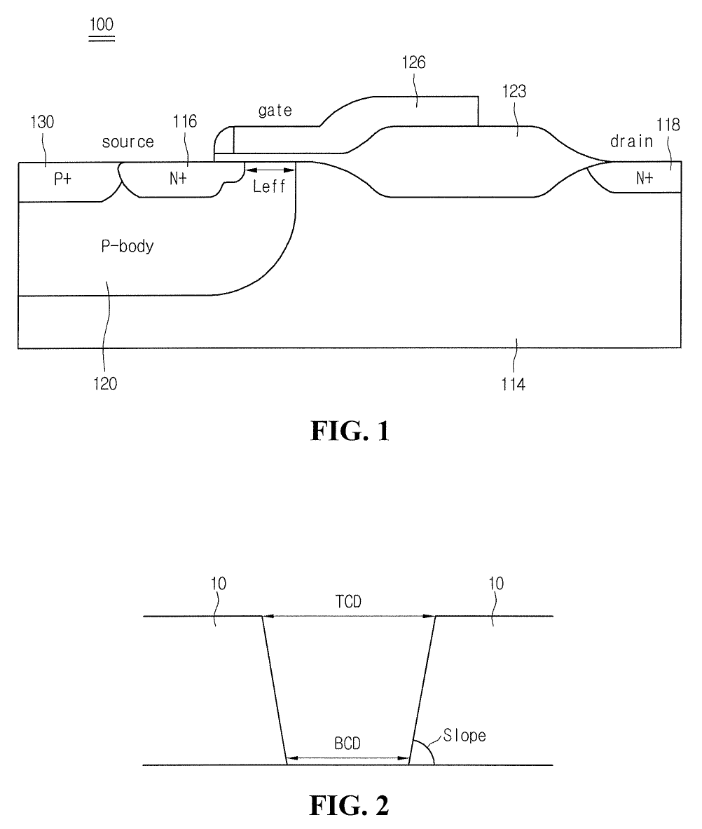

FIG. 1 is an enlarged view illustrating a method of fabricating a lateral double diffused metal oxide semiconductor field effect transistor (hereinafter, referred to as LDMOS transistor) according to an embodiment.

Referring to FIG. 1, an LDMOS transistor 100 is configured such that an n-well region 114 is formed in a semiconductor substrate and a p-body region 120 is formed at a side portion of the n-well region 114.

In addition, the LDMOS transistor 100 includes a source region 116 and a drain region 118. The source region 116, into which n-type impurities are implanted, is formed in the p-body region 120. Furthermore, a heavily doped body region 130 is formed in the p-body region 120 to have excellent contact with respect to the p-body region 120.

The drain region 118 is formed separated from the p-body region 120 and adjacent to one end of a field isolation region 123. The field isolation region 123 can include a field oxide layer such as silicon oxide or the like which is thermally grown.

A gate electrode 126 is formed on the source region 116 and the field isolation region 123 such that it extends from a portion of the source region 116 to a portion of the field isolation region 123.

Meanwhile, a p-channel is self-aligned using a difference in diffusion coefficient between the n-type impurity and the p-type impurity in the LDMOS transistor 100. In brief, the self-aligning of the p-channel may be performed in such a way that n-type and p-type impurities with predetermined concentrations are implanted to shallow depths, and diffusion and high-temperature processes are subsequently performed.

In detail, the source region 116 and the p-body region 120 can be formed by the following: implanting p-type impurities such as boron (B) into the substrate; implanting n-type impurities such as arsenic (As) or phosphorous (P) to a shallow depth; diffusing the implanted impurities; and performing a high-temperature process.

The p-type impurity has a higher diffusion coefficient than the n-type impurity so that the p-type impurity diffuses more actively than the n-type impurity in horizontal direction, which makes it possible to obtain the self-aligned p-channel.

The threshold voltage of the LDMOS transistor 100 is defined as a gate voltage triggering a strong inversion at a position of the highest concentration in the p-channel. When the concentrations of the n-type and p-type impurities are set to fixed values, a size of an implantation area, i.e., a bottom critical dimension of a portion where a photoresist is removed during photolithographic process for the p-body region 120, can be used to determine an effective channel length Leff and a channel concentration, and thus the bottom critical dimension (see the reference symbol BCD of FIG. 2) may be a key parameter to change the threshold voltage of the LDMOS transistor 100.

Furthermore, in order to improve a safe operating area (SOA), which is an important characteristic of a power device, the p-type impurities are implanted at high energy during an ion implantation process for forming a channel. In this case, however, the ions may be implanted onto an undesired region depending on a photoresist slope because a high-energy ion implantation is used for forming a low resistance well. Therefore, the p-type impurities, which are implanted for forming a well, have an undesirable effect on the effective channel length Leff and the channel concentration.

Accordingly, in embodiments of the present invention, optimization of the photoresist slope is an important process parameter to stabilize the threshold voltage of the LDMOS transistor 100.

FIG. 2 is a schematic view illustrating a photoresist slope.

Referring to FIG. 2, a photoresist 10 is formed on a substrate structure, and a portion where the photoresist 10 is removed to expose a layer (or substrate) has a top critical dimension (TCD) and a bottom critical dimension (BCD). In addition, the photoresist 10 has a predetermined slope that is inclined at a predetermined angle with respect to a bottom surface.

As described above, according to the present embodiment, the bottom critical dimension (BCD) and the photoresist slope are key process parameters to cause the threshold voltage values to be changed and dispersed.

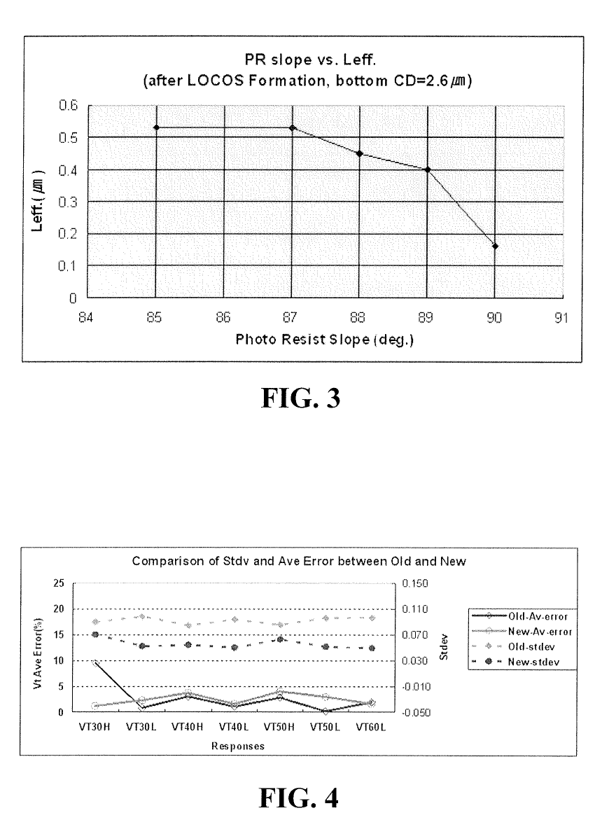

FIG. 3 is a graph illustrating a relation between the photoresist slope and an effective channel length Leff.

In detail, FIG. 3 shows data obtained by simulating the correlation between the photoresist slope and the effective channel length Leff using a 2-D simulator T-supreme.

It can be understood from FIG. 3 that the effective channel length Leff is sharply reduced as a photoresist slope angle approximates 90°.

As described above, the bottom critical dimension (BCD) and the slope affecting the threshold voltage of the LDMOS transistor 100 are determined after the photolithographic process has been performed on the p-body region 120. The bottom critical dimension (BCD) and the slope can be controlled by changing energy and focus conditions of photoexposure process, respectively. Here, the energy corresponds to an exposure time expressed in units of msec.

The energy/focus (E/F) conditions are matrix-split in each shot so that the bottom critical dimension (BCD) and the slope are intentionally changed.

Experiments are performed on a total of 10 lots, and 36 sheets of wafers are used in these experiments. In addition, the experiments are performed on each lot at predetermined time intervals. Therefore, a total of 36 sets of data can be obtained at every E/F condition.

A bottom critical dimension (BCD) and a top critical dimension (TCD) are measured for each of the shots with different E/F conditions, and threshold voltages of 30 V, 40 V, 50 V, and 60 V LDMOS transistors are measured for each shot, respectively. Thereafter, a modeling and an analysis are performed using a statistical analysis tool, e.g., PCM studio.

Conducted are a modeling of the correlation between photolithographic conditions for the p-body region 120 and experimental results such as the bottom critical dimension (BCD), the top critical dimension (TCD) and the threshold voltage of the LDMOS transistor. Through the statistical analysis, E/F conditions are selected, which satisfies a target threshold voltage, 1.3 V, of each device (30 V, 40 V, 50 V, and 60 V LDMOS transistors) and exhibits the best characteristics in terms of threshold voltage dispersion.

As a result of the analysis, an ideal E/F condition is observed at 440 msec/−0.25 where the threshold voltage approximates to 1.3 V most closely and exhibits optimum dispersion characteristic. Furthermore, when the E/F condition is in the range of 400˜480 msec/−0.23˜−0.27 μm, the experimental results also exhibit relatively excellent effects. In this case, it can be shown that the bottom critical dimension (BCD)/top critical dimension (TCD) is 2.61 μm/2.883 μm, respectively.

However, it is nearly impossible to consistently perform an actual process under the ideal E/F condition. Moreover, since a measured critical dimension is only one way to evaluate and control the process quality after the process has been completed, the bottom critical dimension (BCD), the top critical dimension (TCD) and an estimated dispersion data should be calculated in advance under preset E/F conditions, and then ranges of the critical dimension should be provided as a process spec.

E/F standard deviations are quantitatively analyzed using 1000 pieces of random sample data by inputting conditions such that the energy is set to 25/50/75 msec and the focus is set to 0.05/0.1/0.15 μm, respectively. A condition, which can be realized in consideration of process controllability, is that standard deviations of the bottom critical dimension (BCD) and the top critical dimension (TCD) are 0.05 μm when E/F standard deviation is 50 msec/0.1 μm.

To find out how better the threshold voltage and the threshold voltage dispersion are improved under the selected condition, data obtained under the conditions selected through the above experiments and a related art condition, i.e., E/F condition of 850 msec/0.0 μm, are compared with each other. From the comparison results, it is observed that the threshold voltage constantly approximates about 1.3 V and the threshold voltage dispersion is improved by 40% better than that under the related art condition, i.e., improved from 0.092 to 0.056 on the average, in every device under the selected E/F conditions.

FIG. 4 is a graph illustrating comparison results of threshold voltage characteristics respectively obtained under the related art conditions and optimum conditions selected through the experiments.

Referring to FIG. 4, when an average bottom critical dimension, an average top critical dimension, and a standard deviation (Stdev) are maintained as 2.61 μm, 2.88 μm (in this case, a slope is 87°), and 0.05 μm, respectively, the threshold voltage dispersion of the LDMOS transistor can be controlled to a level of about 0.06 V, which is a 40%-improved value in comparison with that obtained under the related art E/F condition. Therefore, a circuit designer can design an LDMOS transistor with a stable threshold voltage.

The assumption made above that the state of the photoresist varied with exposure conditions of the photolithographic process of the p-body region 120 causes a great change in the threshold voltage of the LDMOS transistor, is quantitatively verified through various statistical access using extracted models.

When the photoresist slope is not changed, the threshold voltage decreases with a relatively linear slope as the bottom critical dimension increases. It is considered that this is caused by the fact that the length of the p-channel is shortened as an area of the p-body region where ions are implanted increases.

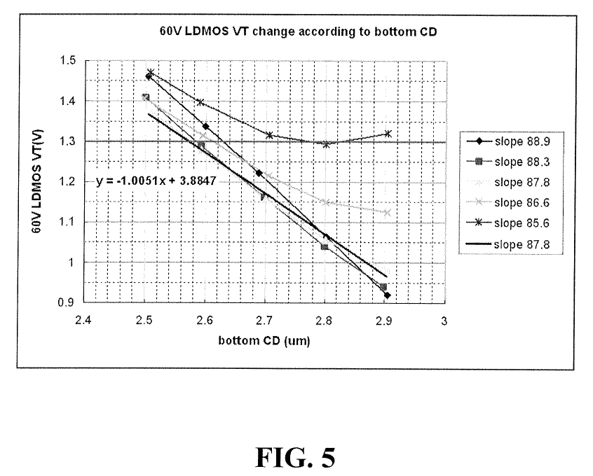

These characteristics are illustrated in FIG. 5. Specifically, when a 60 V LDMOS transistor has a photoresist slope angle of about 87° or greater, the threshold voltage decreases by 0.1 V as the bottom critical dimension (BCD) increases by 0.1 μm.

It can be observed that there is a specific slope angle minimizing the threshold voltage dispersion when the bottom critical dimension (BCD) is constant.

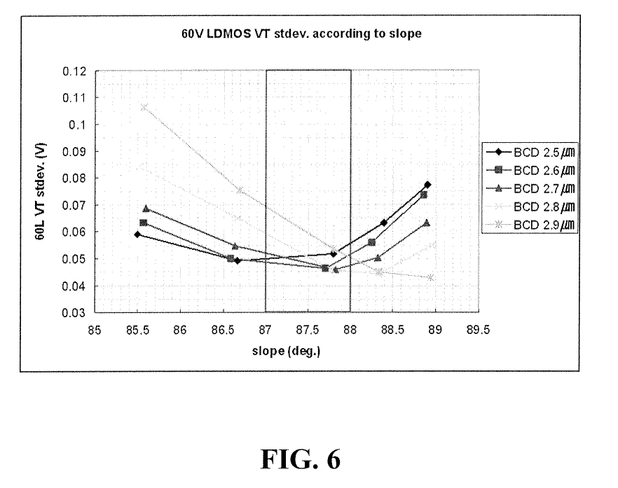

FIG. 6 illustrates that devices into which ions are implanted under condition that the photoresist has a slope angle between 87° and 88°, exhibit the most excellent threshold voltage dispersion among devices having photoresists having a variety of bottom critical dimensions (BCDs).

The reason is that it is difficult to control the photoresist slope when the photoresist slope angle is greater or smaller than an optimum slope angle.

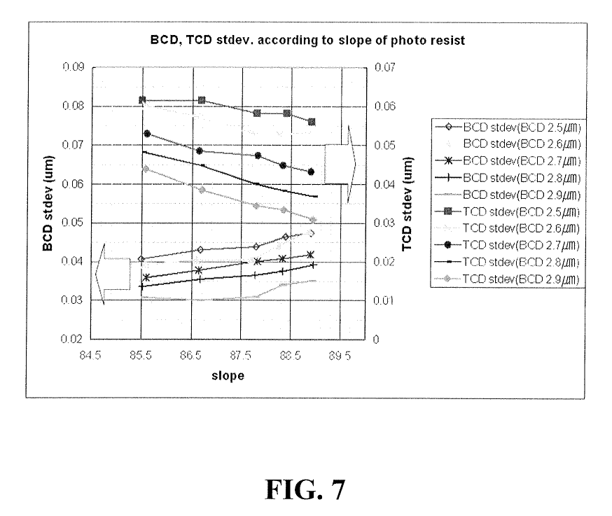

FIG. 7 illustrates that the bottom critical dimension (BCD) is difficult to control (the dispersion becomes great) as the slope becomes great (slope is steep), whereas the top critical dimension (TCD) is difficult to control (the dispersion becomes great) as the slope becomes small (slope is gentle).

In addition, FIG. 7 also illustrates that the threshold voltage dispersion decreases as the top and bottom critical dimensions increase when the photoresist slope has a fixed slope angle.

As described above, the threshold voltage can be changed depending on the bottom critical dimension (BCD), and the threshold voltage dispersion can be controlled if the photoresist slope is maintained at an appropriate angle. From this result, it is possible to provide important guidelines for changing the threshold voltage and process conditions and managing them.

In an embodiment, through the experiments of changing several conditions of the photolithographic process for the p-body, which is an important process to determine the threshold voltage of the LDMOS transistor, ideal process conditions are selected. Furthermore, the correlation between the photolithographic process condition and the threshold voltage is observed.

In order to obtain a relatively constant threshold voltage of the LDMOS transistor with small dispersion, it is preferred to maintain the bottom critical dimension and the top critical dimension at 2.61 μm and 2.88 μm, respectively, and to control process condition such that the standard deviation is within about 0.05 μm. When adopting the above-described conditions, the threshold voltage dispersion can be improved by 40% better than that under the related art condition.

A process parameter greatly affecting the threshold voltage change is the bottom critical dimension (BCD) which can be changed with the photolithographic process condition for the p-body region. Here, the threshold voltage decreases by 0.1 V as the bottom critical dimension increases by 0.1 μm.

According to embodiments, the photoresist slope is maintained to be within a predetermined angle range. The slope, which is less sensitive to the bottom critical dimension and minimizes the threshold voltage dispersion, is in the range of 87° to 88°.

From the results of the experiment and analysis as described above, the threshold voltage of the LDMOS transistor can be effectively managed, and thus a circuit designer can design an LDMOS transistor with a reliable threshold voltage.

In addition, a stable threshold voltage can be obtained through quantitative relation between the threshold voltage of the LDMOS transistor and the process conditions.

Accordingly, embodiments of the present invention can provide a method of stably securing the threshold voltage of the LDMOS transistor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a lateral double diffused metal oxide semiconductor field effect transistor (LDMOS transistor), the method comprising:
implanting ions onto a substrate to form a body region of a LDMOS transistor using a photoresist pattern as an ion implantation mask, wherein the photoresist has a slope with an angle in the range of 87° to 88°.

2. The method according to claim 1, wherein a bottom critical dimension of a removed portion of the photoresist pattern is in the range of 2.56 μm to 2.66 μm.

3. The method according to claim 1, wherein a top critical dimension of a removed portion of the photoresist pattern is in the range of 2.83 μm to 2.93 μm.

4. A method of fabricating an LDMOS transistor, the method comprising:
exposing and developing a photoresist to form a photoresist pattern for a body region of a LDMOS transistor; and
implanting ions onto a substrate to form the body region of the LDMOS transistor using the photoresist pattern as an ion implantation mask,
wherein an exposure time of the photoresist is in the range of 400 msec to 480 msec and a focus is in the range of −0.23 μm to −0.27 μm.

5. The method according to claim 4, wherein a bottom critical dimension of a removed portion of the photoresist pattern is in the range of 2.56 μm to 2.66 μm.

6. The method according to claim 4, wherein a top critical dimension of a removed portion of the photoresist pattern is in the range of 2.83 μm to 2.93 μm.

7. The method according to claim 4, wherein the photoresist pattern has a slope with an angle in the range of 87° to 88°.
